(19) United States
(12) Patent Application Publication
(10) Pub. No.: US 2025/0208515 A1
(43) Pub. Date: Jun. 26, 2025

(54) PAINTING METHOD

(71) Applicant: ASUSTEK COMPUTER INC., TAIPEI (TW)

(72) Inventors: Guo-Lin YANG, TAIPEI (TW); Po-Wen HUANG, TAIPEI (TW); Yu-Chun YANG, TAIPEI (TW); Er-Bao NIU, TAIPEI (TW); Tao CHEN, TAIPEI (TW)

(21) Appl. No.: 18/626,933

(22) Filed: Apr. 4, 2024

(30) Foreign Application Priority Data
Dec. 21, 2023 (TW) 112150115

(51) Int. Cl. G03F 7/00; C09D 5/00; C09D 133/04; C09D 175/04; G03F 7/16

(52) U.S. Cl. CPC G03F 7/70025; C09D 5/002; C09D 133/04; C09D 175/04; G03F 7/161; G03F 7/168

(57) ABSTRACT

Provided is a painting method, adapted to a housing, and the housing includes a painting surface. The painting method includes: forming a primer layer on the painting surface; forming a contour material layer on the primer layer, and defining a pattern range on the contour material layer, and removing the contour material layer within the pattern range in a high temperature processing manner to form a contour layer with a 3D texture.

### CROSS-REFERENCE TO RELATED APPLICATION

This application claims the priority benefit of Taiwan Application Serial No. 112150115, filed on Dec. 21, 2023. The entirety of the above-mentioned patent application is hereby incorporated by reference herein and made a part of specification.

### BACKGROUND OF THE INVENTION

### Field of the Invention

The disclosure relates to a decoration method of a housing surface, and in particular, to a painting method.

### Description of the Related Art

With the development of technologies, portable electronic devices such as mobile phones and a notebook computers are increasingly popular. In addition, people have increasingly high requirements for the appearance of electronic devices.

Traditionally, painting technologies used for the housing of electronic devices mainly include anodizing and spray painting. However, these flat painting technologies cannot provide a 3D layered effect or present multilayer colors on the housing.

### BRIEF SUMMARY OF THE INVENTION

The disclosure provides a painting method, adapted to a housing, and the housing includes a painting surface. The painting method includes: forming a primer layer on the painting surface; forming a contour material layer on the primer layer; and defining a pattern range on the contour material layer, and removing the contour material layer within the pattern range by performing high temperature processing on the contour material layer within the pattern range to form a contour layer with a 3D texture.

Through the painting method provided in the disclosure, a general spray painting process only needs to be used with the high temperature processing to form the contour layer with the 3D texture, so that the housing presents a 3D layered effect, and it is conducive to making the housing present multilayer colors.

### BRIEF DESCRIPTION OF THE DRAWINGS

FIG. 1 is a flowchart of a painting method according to an embodiment of the disclosure;

FIG. 2A and FIG. 2B are schematic structural diagrams showing the painting method in FIG. 1;

FIG. 3 is a flowchart of a painting method according to another embodiment of the disclosure;

FIG. 4A to FIG. 4C are schematic structural diagrams showing the painting method in FIG. 3;

FIG. 5 is a flowchart of a painting method according to another embodiment of the disclosure; and

FIG. 6A to FIG. 6C are schematic structural diagrams showing the painting method in FIG. 5.

### DETAILED DESCRIPTION OF THE EMBODIMENTS

The following will describe specific implementations of the disclosure in more detail with reference to drawings. According to the following description and scope of patent application, advantages and characteristics of the disclosure will be clearer. It should be noted that, drawings adopt a very simplified form and use a non-precise proportion, and are only used for conveniently and clearly illustrating embodiments of the disclosure.

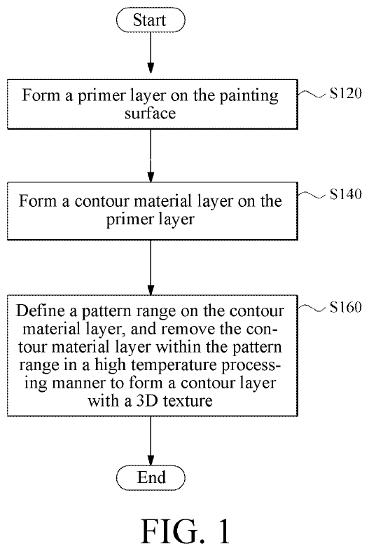

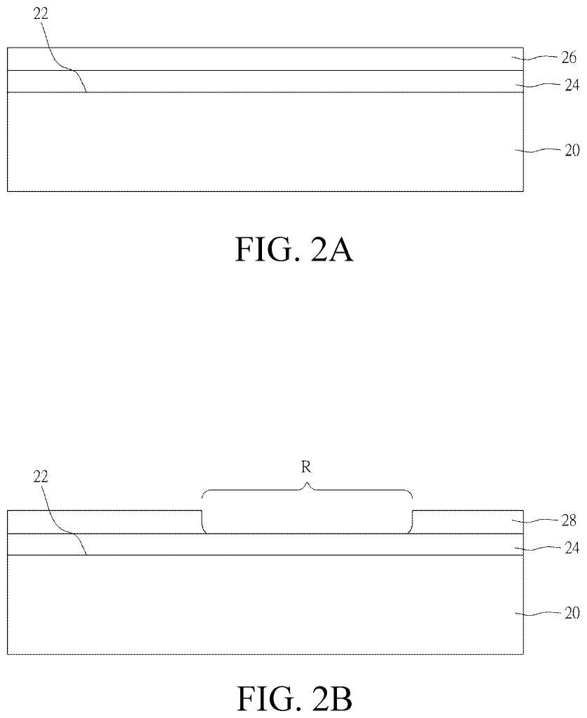

FIG. 1 is a flowchart of a painting method according to an embodiment of the disclosure. FIG. 2A and FIG. 2B are schematic structural diagrams showing the painting method in FIG. 1.

The painting method is adapted to a housing 20, and the housing 20 includes a painting surface 22 adapted for coating paint. In an embodiment, the housing 20 is a metal housing, such as an aluminum alloy housing. In an embodiment, the painting surface 22 is an external surface of the housing 20, which undergoes appropriate surface cleaning processing.

The housing 20 is made by plastic injection molding, die casting, stamping, computer numerical processing (CNC), or the like. The housing 20 is a plastic housing or a metal housing.

The painting method includes the following steps.

First, as described in step S120, a primer layer 24 is formed on a painting surface 22. In an embodiment, the primer layer 24 is formed on the painting surface 22 by atomizing spray paint.

Then, as described in step S140, a contour material layer 26 is formed on the primer layer 24. In an embodiment, the contour material layer 26 is formed on the primer layer 24 by atomizing spray paint. The foregoing steps S120 and S140 are preferably performed in a clean room, and a dust fall condition in step S140 is stricter than that in step S120.

The primer layer 24 is made of a first material, the contour material layer 26 is made of a second material, and heat resistance of the first material is superior to that of the second material. In addition, the first material and the second material are selected such that no chemical reaction happens at an interface between the first material and the second material at a room temperature. In other words, the contour material layer 26 is temporarily adsorbed on the primer layer 24.

In an embodiment, the primer layer 24 is a secondary hydroxyl film layer, and the contour material layer 26 is a water-based polyurethane film layer. Heat resistance of the secondary hydroxyl film layer is superior to that of the water-based polyurethane film layer.

In an embodiment, a constituent material of the primer layer 24 includes 23-29 wt % of oligomer polyol, 7-11 wt % of high solid polyurea, and 15-21 wt % of modified acrylic, 2.5-3.5 wt % of polytetrahydrofuran ether alcohol, 8-16 wt % of cross-linked monomer material, and 3-5 wt % of cross-linked modified material.

In an embodiment, a constituent material of the contour material layer 26 includes 23-29 wt % of oligomer polyol, 31-43 wt % of water-based polyurethane, 1-2 wt % of mineral defoamer, 1.5-2.0 wt % of chain extender, and 3-5 wt % of cross-linked modified material. In an embodiment, a thickness of the contour material layer 26 ranges from 5 to 15 microns, and a thickness of the primer layer 24 ranges from 5 to 15 microns.

In an embodiment, before the step of forming the secondary hydroxyl film layer on the painting surface 22 (that is, step S120), the housing 20 needs to be placed in an environment with a temperature of 65° C.-75° C. to dry for 20-40 minutes. After the secondary hydroxyl film layer is formed, the housing 20 needs to be left in a room temperature environment for 1-2 hours, and then step S140 is performed.

In the step of forming the water-based polyurethane film layer on the secondary hydroxyl film layer (that is, step S140), a humidity on a product surface needs to be maintained at 30%-40%. After the water-based polyurethane film layer is formed, it needs to be dried in an environment with a temperature of 70° C.-80° C. for 5-10 minutes, and then left in an environment with a temperature of 18° C.-23° C. and the humidity of 45%-65% for 30-60 minutes, and then the subsequent step S160 is performed.

Next, as described in step S160, a pattern range R is defined on the contour material layer 26, and the contour material layer 26 within the pattern range R is removed in a high temperature processing manner to form a contour layer 28 with a 3D texture. This step is understood as performing positioning and fat-removing processing on the contour material layer 26 to form the 3D texture.

In an embodiment, step S160 is performing high temperature processing on the contour material layer 26 within the pattern range R by irradiating laser light to remove the contour material layer 26 within the pattern range R. In an embodiment, a jig is used to position the housing 20, corresponding coordinates of the pattern range R are set, and then a laser processing system is used to remove the contour material layer 26 within the pattern range R.

In an embodiment, as shown in the figure, step S160 is completely removing the contour material layer 26 within the pattern range R. In other embodiments, only part of the contour material layer 26 within the pattern range R is removed, that is, the thickness of the contour material layer 26 is reduced to form a 3D texture.

It should be noted that since the heat resistance of the primer layer 24 is superior to that of the contour material layer 26, and no chemical reaction happens at an interface between the primer layer 24 and the contour material layer 26 at a room temperature, the contour material layer 26 within the preset pattern range R is effectively removed by appropriately adjusting the power and irradiation time of the laser light, without causing damage to the primer layer 24 below the contour material layer 26.

Specifically, since the painting surface 22 is not necessarily horizontal, in an embodiment, step S160 is using a probe to determine a height position of the contour material layer 26 within the pattern range R, and establishing a model of the painting surface 22 with multi-point data captured by 3D scanning, to determine the position of the pattern range R to be removed by laser processing.

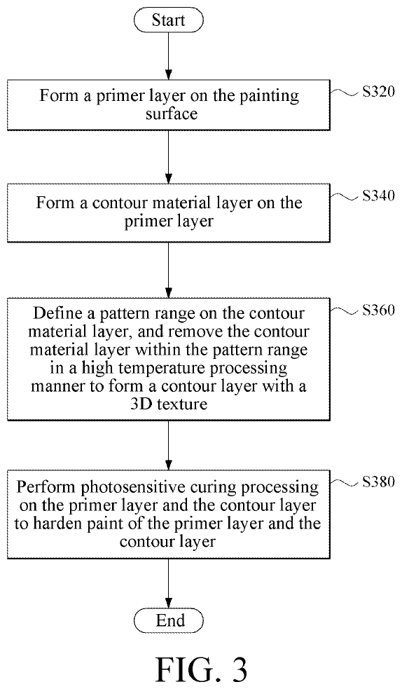

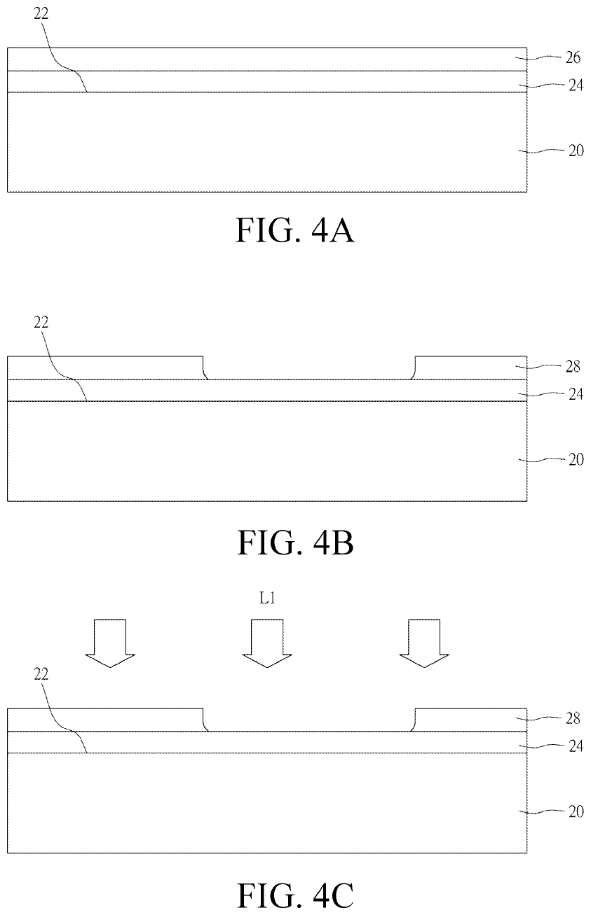

FIG. 3 is a flowchart of a painting method according to another embodiment of the disclosure. FIG. 4A to FIG. 4C are schematic structural diagrams showing the painting method in FIG. 3. The painting method is adapted to a housing 20, and the housing 20 includes a painting surface 22.

Steps S320, S340, and S360 of this embodiment are the same as those of the embodiment in FIG. 1. Compared with the embodiment in FIG. 1, after step S260 of removing the contour material layer 26 within the pattern range R to form the contour layer 28 with the 3D texture, this embodiment further includes step S380 of performing photosensitive curing processing on the primer layer 24 and the contour layer 28 to harden paint of the primer layer 24 and the contour layer 28. In an embodiment, the photosensitive curing processing is irradiating exposed parts of the contour layer 28 and the primer layer 24 with ultraviolet light LI from a front side of the painting surface 22 to harden the paint of the contour layer 26 and the primer layer 24. This step is understood as performing high hardness processing on the paint layer on the painting surface 22.

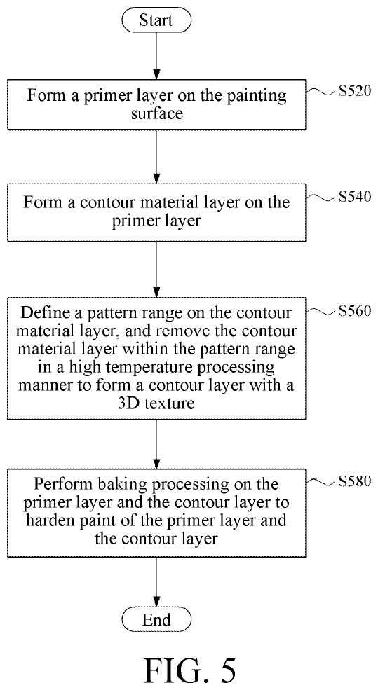

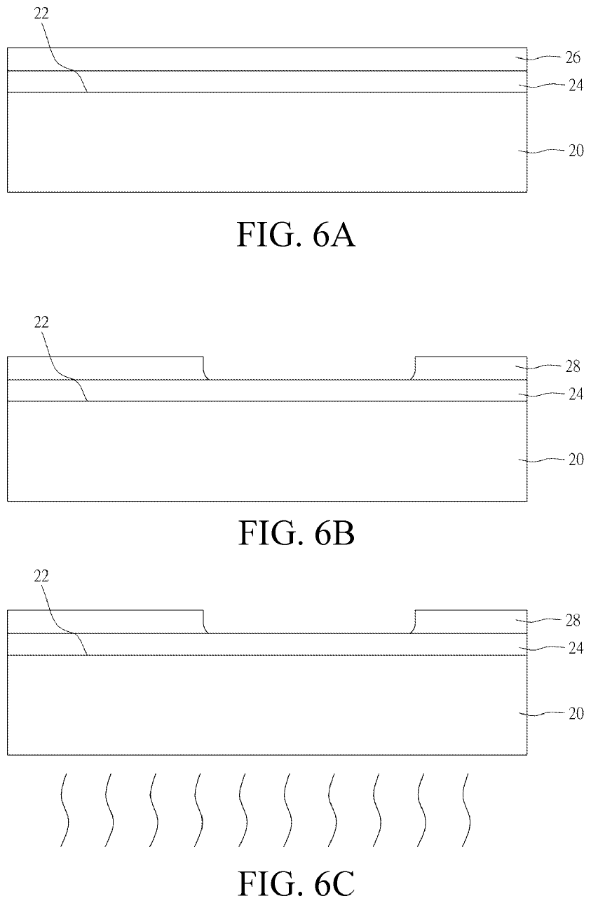

FIG. 5 is a flowchart of a painting method according to another embodiment of the disclosure. FIG. 6A to FIG. 6C are schematic structural diagrams showing the painting method in FIG. 5. The painting method is adapted to a housing 20, and the housing 20 includes a painting surface 22.

Steps S520, S540, and S560 of this embodiment are the same as those of the embodiment in FIG. 1. Compared with the embodiment in FIG. 1, after step S360 of removing the contour material layer 26 within the pattern range R to form the contour layer 28 with the 3D texture, this embodiment further includes step S580 of performing baking processing on the primer layer 24 and the contour layer 28 to harden paint of the primer layer 24 and the contour layer 28. In an embodiment, the baking processing is heating the primer layer 24 and the contour layer 28 from a rear surface of the housing 20 relative to the painting surface 22 to harden the paint of the contour layer 28 and the primer layer 24. This step is understood as performing low hardness processing on the paint layer on the painting surface 22.

Through the painting method provided in the disclosure, a general spray painting process only needs to be used with the high temperature processing at a specific position to form the contour layer 28 with the 3D texture, so that the housing 20 presents a 3D layered effect. If the primer layer 24 and the contour material layer 26 are given different colors, it is conducive to making the housing 20 present multilayer colors.

The above are only exemplary embodiments of the disclosure but do not limit the disclosure. Variations such as equivalent replacements or modifications in any form made by any person skilled in the art to the technical means and technical contents disclosed in the disclosure without departing from the technical means of the disclosure are contents not departing from the technical means of the disclosure and still fall within the protection scope of the disclosure.

What is claimed is:

1. A painting method, adapted to a housing, wherein the housing comprises a painting surface, and the painting method comprises:
forming a primer layer on the painting surface;
forming a contour material layer on the primer layer; and
defining a pattern range on the contour material layer, and removing the contour material layer within the pattern range in a high temperature processing manner to form a contour layer with a 3D texture.

2. The painting method according to claim 1, wherein the primer layer is made of a first material, the contour material layer is made of a second material, and heat resistance of the first material is superior to that of the second material.

3. The painting method according to claim 2, wherein no chemical reaction happens at an interface between the first material and the second material at a room temperature.

4. The painting method according to claim 1, wherein the primer layer is a secondary hydroxyl film layer, and the contour material layer is a water-based polyurethane film layer.

5. The painting method according to claim 4, wherein a constituent material of the primer layer comprises 23-29 wt % of oligomer polyol, 7-11 wt % of high solid polyurea, 15-21 wt % of modified acrylic, 2.5-3.5 wt % of polytetrahydrofuran ether alcohol, 8-16 wt % of cross-linked monomer material, and 3-5 wt % of cross-linked modified material.

6. The painting method according to claim 4, wherein a constituent material of the contour material layer comprises 23-29 wt % of oligomer polyol, 31-43 wt % of water-based polyurethane, 1-2 wt % of mineral defoamer, 1.5-2.0 wt % of chain extender, and 3-5 wt % of cross-linked modified material.

7. The painting method according to claim 1, wherein the step of removing the contour material layer within the pattern range in a high temperature processing manner is removing the contour material layer within the pattern range by using laser light.

8. The painting method according to claim 1, wherein a thickness of the contour material layer ranges from 5 to 15 microns.

9. The painting method according to claim 1, wherein a thickness of the primer layer ranges from 5 to 15 microns.

10. The painting method according to claim 1, further comprising: performing photosensitive curing processing on the primer layer and the contour layer.

11. The painting method according to claim 10, wherein the photosensitive curing processing is irradiating exposed parts of the contour layer and the primer layer with ultraviolet light from a front side of the painting surface.

12. The painting method according to claim 1, further comprising: performing baking processing on the primer layer and the contour layer.

13. The painting method according to claim 12, wherein the baking processing is heating the primer layer and the contour layer from a rear side of the painting surface.
